(19) United States
(12) Patent Application Publication
(10) Pub. No.: US 2007/0026545 A1
(43) Pub. Date: Feb. 1, 2007

(54) Methods and systems for controlling semiconductor device manufacturing processes

(76) Inventors: Jin-ho Hwang, Gyeonggi-do (KR); Chan-ki Yang, Gyeonggi-do (KR); Jae-won Hwang, Gyeonggi-do (KR)

Correspondence Address: MYERS BIGEL SIBLEY & SAJOVEC, PO BOX 37428, RALEIGH, NC, 27627, US

(21) Appl. No.: 11/495,983

(22) Filed: Jul. 28, 2006

(30) Foreign Application Priority Data
Jul. 29, 2005 (KR) 10-2005-0069666

(51) Int. Cl. H01L 21/66; H01L 21/302

(52) U.S. Cl. 438/14; 438/691; 257/E21.53

(57) ABSTRACT

A first process time period for a manufacturing process is determined, and a thickness of a material on a sample semiconductor substrate using the first process time period is measured. If the thickness is not within a desired thickness range, a second process time period for the manufacturing process for obtaining a thickness in the desired thickness range is determined. If the thickness is within a desired thickness range, a third process time period for a subsequent manufacturing process based on a change in the manufacturing process over time is determined.

### CROSS-REFERENCE TO RELATED PATENT APPLICATIONS

This application claims priority to Korean Patent Application No. 10-2005-0069666, filed on Jul. 29, 2005, in the Korean Intellectual Property Office, the disclosure of which is incorporated by reference herein in its entirety.

### BACKGROUND OF THE INVENTION

1. Field of the Invention

The present invention relates to an apparatus and method of manufacturing a semiconductor device, and more particularly, to a system and method of controlling a semiconductor device manufacturing process.

2. Description of the Related Art

Examples of typical manufacturing processes for manufacturing semiconductor devices include the crystal growth of a semiconductor material, the division of the semiconductor crystal into individual wafers, etching, doping, ion-implantation, packaging, and testing. These processes can be performed in different processing locations under specified conditions to control the manufacturing processes. A control system for controlling various process conditions may be used for each of the processes.

Adjusting the period of time to perform the process (the “process time period”) can control the processing results, such as the layer thicknesses and other properties of the wafer. For example, the process time period can be controlled to achieve certain results for rapid thermal treatment processes, chemical mechanical planarization (CMP) processes, overlay processes, physical deposition processes, chemical deposition processes, spin coating processes, etc.

For example, for a CMP process, the thickness of the material removed by the CMP process depends on the process time period. A conventional CMP process is divided into a sample CMP and a main CMP. In the sample CMP, a removal rate (Å/sec) is determined based on a blanket oxide wafer, which is not patterned. The time period to process an actual wafer (e.g., to remove a thickness of the material on the wafer) is empirically calculated using the removal rate of the sample CMP.

When a thickness deviation of the sample CMP is within an allowable range, the main CMP is performed. The process time period is controlled by continuously detecting thicknesses of lots that have undergone the main CMP and manually feeding the result of the detection back to the main CMP. For example, when a removed thickness of a lot after completion of main CMP is greater than a desired target thickness, the process time period is subsequently reduced. When the removed thickness of a lot after completion of main CMP is smaller than the desired target thickness, the process time period is increased. All of process time periods are empirically obtained. This empirical technique may be effective in a CMP process on one type of product.

However, in a production line for a product various types of products, for example, a system large scale integration (LSI), can use different process time periods for the various products because the various products have different pattern densities. Conventionally, the process time periods are empirically collected and tabled based on the type of product (i.e., a process time table). When a particular product reaches the CMP process, a process time period corresponding to the product is selected from the process time table, and the product is processed for the selected process time period.

In addition, for a typical CMP process, the removal rate of the polishing pad decreases as time passes, which may result in increased thickness variations.

### SUMMARY OF THE INVENTION

According to embodiments of the present invention, methods of controlling a semiconductor manufacturing process to obtain a desired thickness of a material on a semiconductor device are provided. A first process time period for a manufacturing process is determined, and a thickness of a material on a sample semiconductor substrate using the first process time period is measured. If the thickness is not within a desired thickness range, a second process time period for the manufacturing process for obtaining a thickness in the desired thickness range is determined. If the thickness is within a desired thickness range, a third process time period for a subsequent manufacturing process based on a change in the manufacturing process over time is determined.

According to further embodiments of the present invention, systems for controlling a semiconductor manufacturing process to obtain a desired thickness of a material on a semiconductor device include a control unit configured to determine a first process time period for a manufacturing process and to obtain a measured thickness of a material on a sample semiconductor substrate after the manufacturing process. The control unit is configured to determine a second process time period for the manufacturing process for obtaining a thickness in the desired thickness range if the thickness is not within a desired thickness range. The control unit is configured to determine a third process time period based on a change in the manufacturing process over time if the thickness is within a desired thickness range.

According to further embodiments of the present invention, methods of controlling a semiconductor device manufacturing process include determining a first process time period according to the following sample control formula given by:
Sample control formula=ax+b,
wherein a and b denote constants, and x denotes a change rate.
   A sample chemical mechanical planarization process is performed during the first process time period. A variation of a target of a chemical mechanical planarization process after completion of the sample chemical mechanical planarization process is measured. A third process time period for an n-th stage is determined according to the following process control formula, if the variation of the target is within an allowable range:
   Process control formula=F(T)×F(Z),
   wherein F(T)=f(t)n/f(t)n−1, F(Z)=TPR(n−1)−[TTG(n−1)−TAT(n−1)]/RRM(n−1), f(t)n and f(t)n−1 denote a process time period for the n-th stage and a process time period for the (n−1)th stage, respectively, and TPR(n−1), TTG(n−1), TAT(n−1), and RRM(n−1) denote a variation of the target, a target value of the target, an actual value of the target, and a change rate of the actual value, respectively, for the (n−1)th stage.

### BRIEF DESCRIPTION OF THE DRAWINGS

FIG. 1 is a schematic view of a control system according to embodiments of the present invention, for example, an advanced process control (APC) system;

FIG. 2 is a flowchart illustrating methods according to embodiments of the present invention;

FIG. 3 is a graph of a sample control formula;

FIG. 4 is a graph of a removal rate for each product stage;

FIG. 5 is a graph of a thickness of a chemical mechanical planarization (CMP) target as a function of pattern density after a main CMP with respect to an n-th stage is completed;

FIG. 6 is a graph showing a thickness of a CMP target after a CMP process is completed according to a conventional process timetable and a thickness of a CMP target after a CMP process is completed according to embodiments of the present invention; and

FIGS. 7A and 7B are graphs showing a process capability index when a CMP process is completed according to a conventional process timetable and a process capability index when a CMP process is completed according to embodiments of the present invention, respectively.

### DETAILED DESCRIPTION OF THE INVENTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items. Like numbers refer to like elements throughout.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in the Figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be understood that the some embodiments of the present invention are described herein with respect to flowchart diagrams. It should also be noted that, in some alternative implementations, the operations noted in the flowcharts may occur out of the order noted in the figures. For example, two blocks shown in succession may, in fact, be executed substantially concurrently, or the blocks may sometimes be executed in the reverse order.

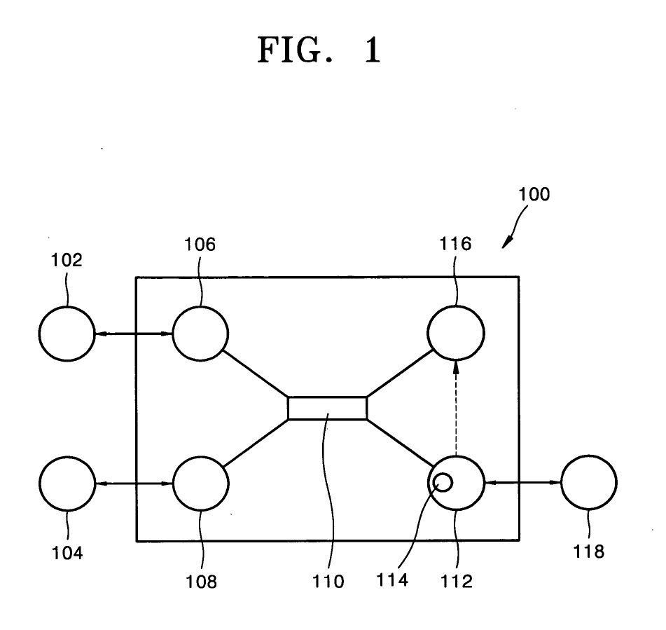

FIG. 1 is a schematic view of a control system, such as an advanced process control (APC) system 100, according to embodiments of the present invention. Referring to FIG. 1, the APC system 100 includes software, which performs process control and defect detection. The APC system 100 includes a machine interface 106, which collects information obtained by an external process unit 102, and a sensor interface 108 connected to an external sensor 104. A plan executer 116 controls the APC system 100, for example, by providing a possible solution in consideration of a detected defect.

The APC system 100 further includes an application interface 112, which applies information received from the sensor interface 108 and the machine interface 106 to external equipment 118. The control unit 114 is a part of the application interface 112. For example, when the control unit 114 determines a process time period, the external equipment 118 can be configured to perform the process using the determined time period. Communications of the machine and sensor interfaces 106 and 108 with the plan executer 116 and the application interface 112 can be achieved through a data channel 110. When the application interface 112 and/or the control unit 114 receives information from the external equipment 118, the interface 112 transmits a copy of the information to the plan executer 116. The application interface 112 (including the control unit 114) can provide information to the plan executer 114 in real time. The components of the APC system 100 receive signals including data information via the data channel 110.

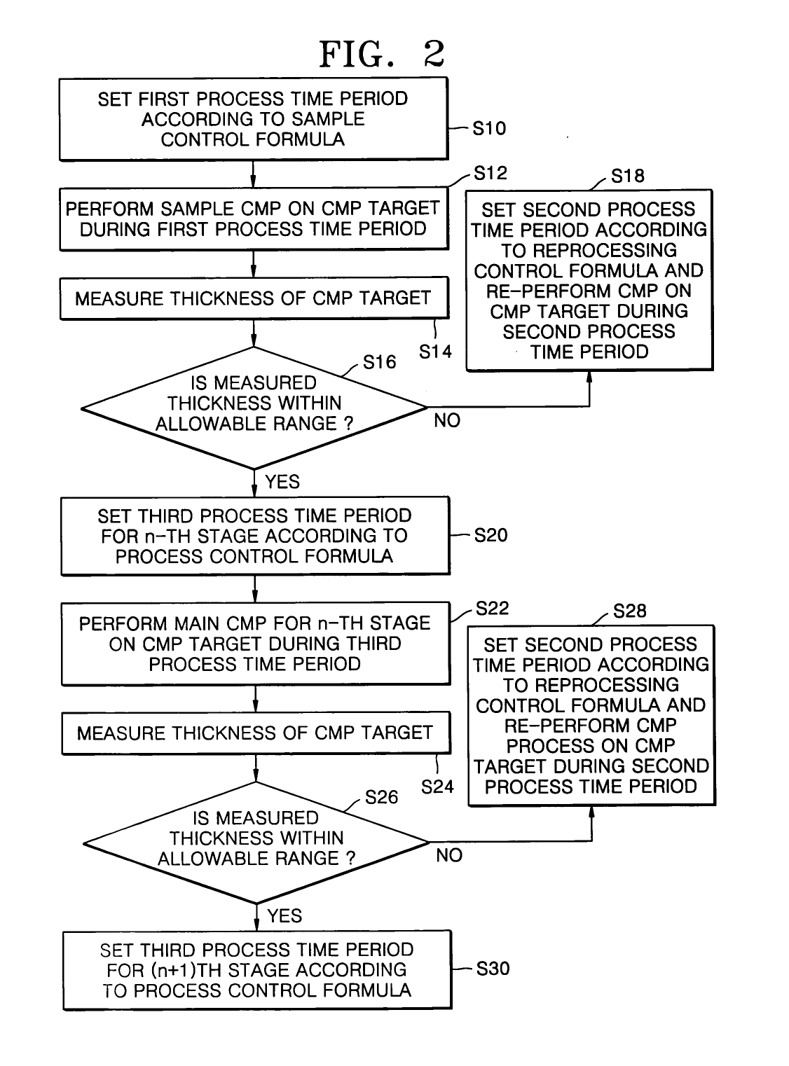

FIG. 2 is a flowchart illustrating controlling methods according to embodiments of the present invention. In FIG. 2, a chemical mechanical planarization (CMP) process is illustrated as a process in which the process time period is controlled. However, it should be understood that the process time period of various types of processes can be controlled as described herein. The n-th stage may correspond to a particular product selected from various products.

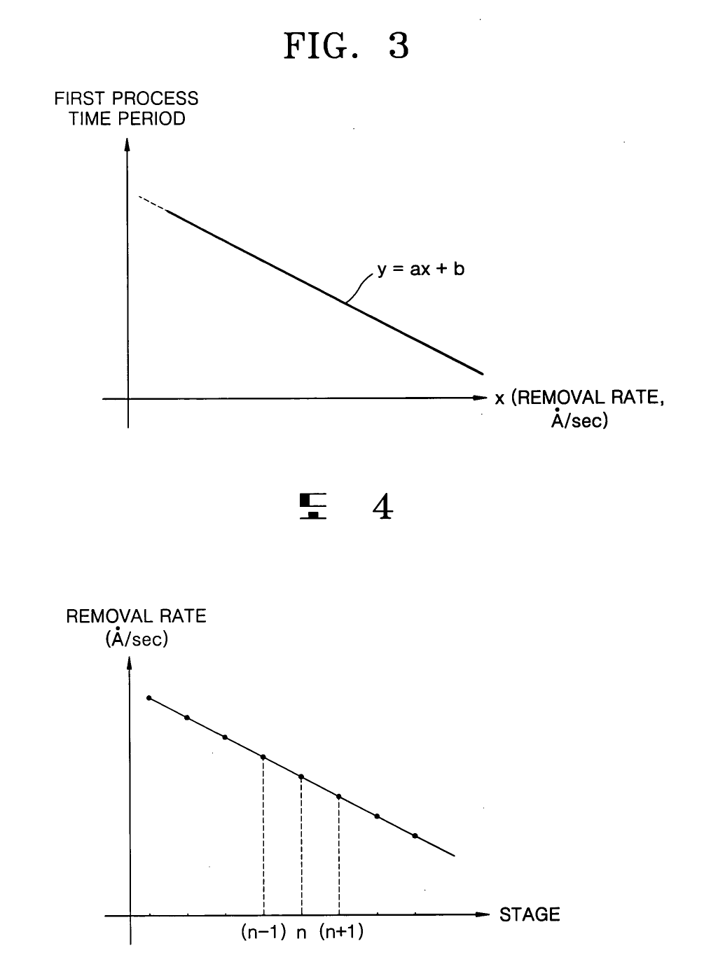

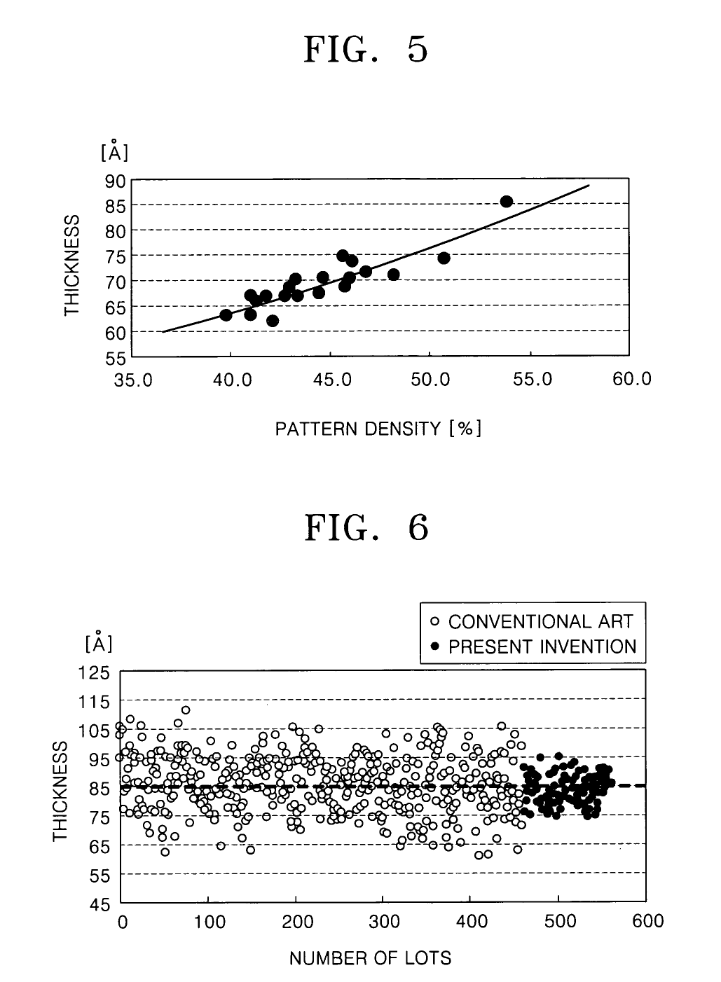

FIG. 3 is a graph showing a sample control formula for a process time period as a function of removal rate. FIG. 4 is a graph showing a removal rate as a function of the stage for various products. FIG. 5 is a graph showing a thickness of a CMP target as a function of pattern density after a main CMP with respect to the n-th stage is completed.

According to embodiments of the present invention, a first process time period for a manufacturing process is determined, and a thickness of a material on a sample semiconductor substrate using the first process time period is measured. If the thickness is not within a desired thickness range, a second process time period for the manufacturing process for obtaining a thickness in the desired thickness range is determined. If the thickness is within a desired thickness range, a third process time period for a subsequent manufacturing process based on a change in the manufacturing process over time is determined. In some embodiments, the manufacturing process is a chemical mechanical planarization (CMP) process, and the third process time period is based on a change in a removal rate for the CMP process. Accordingly, the process time period can be modified based on a secular change, such as such as a decrease in the removal rate of a polishing pad for a CMP process.

Referring to FIG. 2, in Block S10, a first process time period is determined according to the following sample control formula, that is, Equation 1:
Sample control formula=ax+b (1)
wherein a and b denote constants, and x denotes a removal rate. The sample control formula, that is, Equation 1, may be determined in a stage right before the n-th stage, that is, an (n−1)th stage, based on a blanket oxide wafer which is not patterned.

As shown in FIG. 3, the first process time period linearly decreases with an increase of the removal rate (Å/sec). That is, when the removal rate increases, the first process time period decreases. When the removal rate decreases, the first process time period increases. The removal rate denotes a thickness (Å) of a CMP target, such as a copper film, by which the CMP target is removed per time. The first process time period can be calculated by substituting a removal rate obtained from Equation 1 for the graph of FIG. 3.

Thereafter, in Block S12, a sample CMP is performed on the CMP target during the first process time period. In Block S14, a thickness of the CMP target is measured. Here, the thickness of the CMP target denotes a thickness of the CMP target that has undergone the sample CMP process. In Block S16, it is determined whether the measured thickness is within an allowable range. If the measured thickness is within the allowable range, a subsequent process, that is, main CMP, is performed. On the other hand, if the measured thickness is out of the allowable range, a second process time period is determined according to the following reprocessing control formula, that is, Equation 2, and a CMP process is re-performed on the CMP target during the second process time period, in Block S18:
Reprocessing control formula=[TTG(n)−TAT(n)]/RRR(n) (2)
wherein TTG(n), TAT(n), and RRR(n) denote a target thickness, an actual thickness, and a reprocessing removal rate for the n-th stage.

If the measured thickness is within the allowable range, a third process time period for the n-th stage is determined according to the following process control formula, that is, Equation 3, in Block S20:
Process control formula=F(T)×F(Z) (3)
wherein F(T)=f(t)n/f(t)n−1, and F(Z)=TPR(n−1)−[TTG(n−1)−TAT(n−1)]/RRM(n−1). Also, f(t)n and f(t)n−1 denote a process time period for the n-th stage and a process time period for the (n−1)th stage, respectively. TPR(n−1), TTG(n−1), TAT(n−1), and RRM(n−1) denote a predetermined thickness of a CMP target, a target thickness of a CMP target after CMP, an actual thickness of a CMP target after CMP, and a reprocessing removal rate, respectively, for the (n−1)th stage.

As shown in FIG. 4, the third process time period increases as stages proceed, because the removal rate by a polishing pad decreases as a CMP process proceeds. TPR(n−1)−[TTG(n−1)−TAT(n−1)]/RRM(n−1) in Equation 3 makes up for a secular change of the CMP process. In other words, F(Z) considers a change of a process time period caused by a difference between a target thickness and an actual thickness when the (n−1)th stage is processed during the third process time period.

F(Z) assumes that a pattern density of the n-th stage is substantially the same as that of the (n−1)th stage. As shown in FIG. 5, the thickness of a CMP target increases with an increase of the pattern density. The above assumption of F(z) is made to simplify the process control formula, Equation 3, so a change of the pattern density may be considered in an actual process. It should be understood that, in some embodiments, various pattern densities may be used.

Then, in Block S22, a main CMP for the n-th stage is performed on a CMP target, e.g., a copper film, during the third process time period. In Block S24, the thickness of the CMP target is measured. In Block S26, it is determined whether the measured thickness is within the allowable range. If the measured thickness is out of the allowable range, a second process time period is determined according to the above-described reprocessing control formula, Equation 2, and a CMP process is re-performed on the CMP target using the second process time period in Block S28.

If the measured thickness is within the allowable range, a third process time period for an (n+1)th stage is determined according to the following process control formula, that is, Equation 3, in Block S30:
Process control formula=F(T)×F(Z) (3)
wherein F(T)=f(t)n+1/f(t)n, and F(Z)=TPR(n)−[TTG(n)−TAT(n)]/RRM(n). Also, f(y)n+1 and f(y)n denote a process time period for the (n+1)th stage and a process time period for the n-th stage, respectively. TPR(n), TTG(n), TAT(n), and RRM(n) denote a predetermined thickness of a CMP target, a target thickness of a CMP target after CMP, an actual thickness of a CMP target after CMP, and a reprocessing removal rate, respectively, for the n-th stage. Reprocessing in operations S18 and S28 is the same as the CMP process for the n-th stage.

FIG. 6 is a graph showing a thickness of a CMP target after a CMP process is completed according to a conventional process timetable and that after a CMP process is completed according to the above-described process. The first 500 lots undergo CMP according to conventional methods, and 500^{th} lot and afterward undergo CMP according to embodiments of the present invention. In this example, the target thickness of the CMP target is about 85 Å.

Referring to FIG. 6, thicknesses of the CMP targets after the completion of a CMP process according to a conventional process timetable range from about 60 Å to about 120 Å. In particular, the thicknesses of a CMP target according to the conventional process timetable are distributed wider than thicknesses of a CMP target after the completion of a CMP process according to embodiments of the present invention, based on the target thickness of about 85 Å. Therefore, the thicknesses of the CMP targets according to embodiments of the present invention are distributed more narrowly based on the desired target thickness. Because the thicknesses of the CMP targets according to the present invention range from about 95 Å to about 75 Å, the thickness deviation for embodiments of the present invention is reduced compared with that in the prior art.

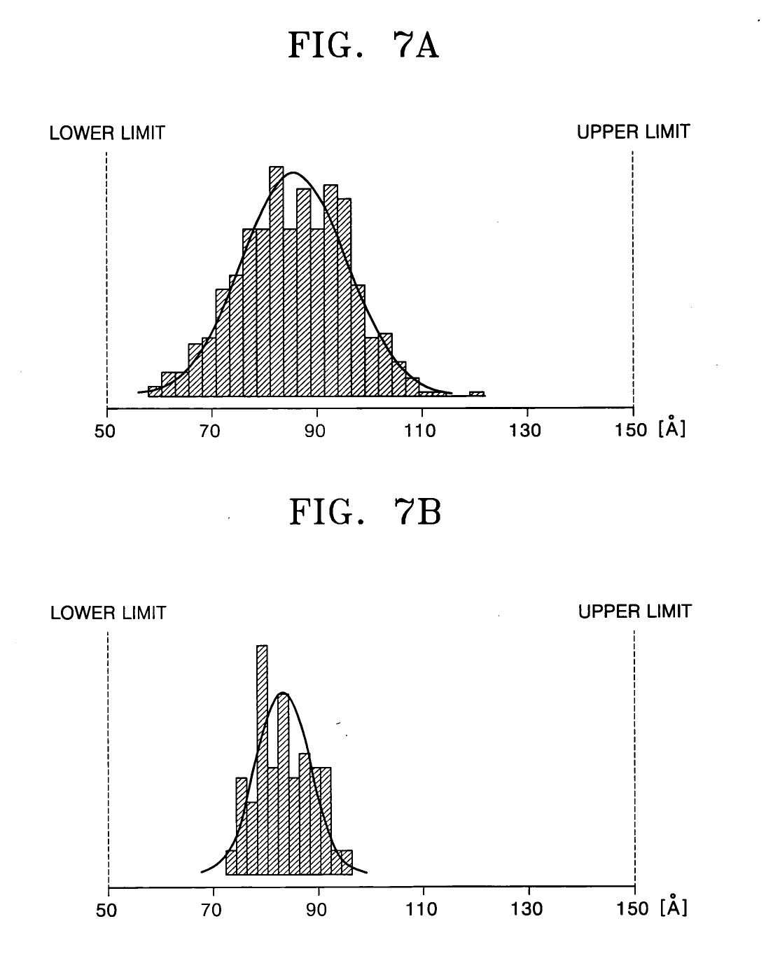

FIGS. 7A and 7B are graphs showing a process capability index when a CMP process is completed according to a conventional controlling methods and that when a CMP process is completed according to embodiments of the present invention, respectively. A lower limit of the thickness of a CMP target is 50 Å, and an upper limit of the thickness of the CMP target is 150 Å.

The term “process capability” denotes the quality of a product that a process can be obtained when the process is in a maintenance (stable) state for obtaining a particular condition, that is, the capability of obtaining a desired target thickness. Examples of methods for utilizing the process capability include a 6σ based method (which presumes 6σ of a quality property distribution and determines the value 6σ for the process capability), a method based on the process capability index, and a method based on a process capability ratio.

In particular, the process capability index is a ratio of the process capability (i.e., 6σ) to a width of an allowable standard and indicates whether the capability of producing a product conforming to the standard is sufficient. Examples of the process capability index include process capability indices Cp, Cpk, and Cpm depending on relationships among the allowable standard, a bias, and a target value, respectively. The process capability index can be utilized in various cases, such as, when the extent to which a tolerance can be maintained is predicted, when a process is selected or changed in a product development stage and a designing stage, when functional requirements of new equipment are prescribed, and when a change of the quality of a manufacturing process is reduced.

The process capability index Cp considers the distribution of a process. The process capability index Cp is used when the allowable standard is given with an upper limit and a lower limit. The process capability index Cp is expressed as various values according to the type of allowable standard. To reflect a degree with which a process capability deviates from the center of the distribution in the process capability index, the center (m) of the allowable standard is (upper limit+lower limit)/2. A bias (k) denotes the degree with which a process average (μ) deviates from the center of the standard. In other words, a process capability index that considers the bias (k), Cpk, is (1-k)Cp. A process capability index Cpk when using an allowable standard given only with an upper limit is (upper limit-μ) σ. A process capability index Cpk when using an allowable standard given only with a lower limit is (μ-lower limit) σ. The process capability index Cpk considers a location of the process average, that is, the bias.

Referring to FIGS. 7A and 7B, process capability indices Cp and Cpk with a conventionally controlled process were 1.66 and 1.19, respectively. On the other hand, process capability indices Cp and Cpk obtained according to embodiments of the present invention were 3.18 and 2.10, respectively. Hence, the controlling methods according to embodiments of the present invention can increase the process capability compared with conventional controlling methods.

According to embodiments of the present invention, the semiconductor device manufacturing process is controlled based on a secular change, such as the decrease in removal rate over time for a polishing pad. The process time period can vary according to the secular change.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of controlling a semiconductor manufacturing process to obtain a desired thickness of a material on a semiconductor device, the method comprising:
determining a first process time period for a manufacturing process;
measuring a thickness of a material on a sample semiconductor substrate using the first process time period;
if the thickness is not within a desired thickness range, determining a second process time period for the manufacturing process for obtaining a thickness in the desired thickness range; and
if the thickness is within a desired thickness range, determining a third process time period for a subsequent manufacturing process based on a change in the manufacturing process over time.

2. The method of claim 1, wherein the manufacturing process is a chemical mechanical planarization (CMP) process, and the third process time period is based on a change in a removal rate for the CMP process.

3. The method of claim 1, wherein the first processing time period is for an (n−1)th processing stage and the third process time period is for an n-th processing stage, the third process time period being determined according to the following process control formula:
Process control formula=F(T)×F(Z),
wherein F(T)=f(t)n/f(t)n−1, F(Z)=TPR(n−1)−[TTG(n−1)−TAT(n−1)]/RRM(n−1), f(t)n and f(t)n−1 denote a process time period for the n-th stage and a process time period for the (n−1)th stage, respectively, and TPR(n−1), TTG(n−1), TAT(n−1), and RRM(n−1) denote a variation of the thickness the target, a target value of the thickness the target, an actual value of the thickness of the target, and a change rate of the actual value of the thickness, respectively, for the (n−1)th stage

4. The method of claim 3, wherein the first process time period is determined according to the following sample control formula:
Sample control formula=ax+b
wherein a and b denote constants, and x denotes a removal rate.

5. The method of claim 4, wherein the sample control formula for the n-th stage is determined according to the process control formula for the (n−1)th stage.

6. The method of claim 4, wherein the removal rate of the sample control formula is determined based on a removal rate of a sample oxide wafer.

7. The method of claim 3, wherein the second process time period is determined according to the following reprocessing control formula:
Reprocessing control formula=[TTG(n)−TAT(n)]/RRR(n)
wherein TTG(n), TAT(n), and RRR(n) denote a target thickness of the material, an actual thickness of the material, and a reprocessing removal rate of the material for the n-th stage.

8. The method of claim 1, wherein the semiconductor manufacturing process is one selected from the group consisting of a rapid thermal treatment process, a chemical mechanical planarization (CMP) process, an overlay process, a physical deposition process, a chemical deposition process, and a spin coating process.

9. The method of claim 1, wherein a pattern density of a product applied to the (n−1)th stage in F(Z) is substantially equal to the pattern density of a product applied to the n-th stage in F(T).

10. A system for controlling a semiconductor manufacturing process to obtain a desired thickness of a material on a semiconductor device, the system comprising:
a control unit configured to determine a first process time period for a manufacturing process and to obtain a measured thickness of a material on a sample semiconductor substrate after the manufacturing process wherein if the thickness is not within a desired thickness range, the control unit is configured to determine a second process time period for the manufacturing process for obtaining a thickness in the desired thickness range, and if the thickness is within a desired thickness range, the control unit is configured to determine a third process time period based on a change in the manufacturing process over time.

11. The system of claim 10, wherein the manufacturing process is a chemical mechanical planarization (CMP) process, and the third process time period is based on a change in a removal rate for the CMP process.

12. The system of claim 10, wherein the first processing time period is for an (n−1)th processing stage and the third process time period is for an n-th processing stage, the control unit being configured to determine the third process time period according to the following process control formula:
Process control formula=F(T)×F(Z),
wherein F(T)=f(t)n/f(t)n−1, F(Z)=TPR(n−1)−[TTG(n−1)−TAT(n−1)]/RRM(n−1), f(t)n and f(t)n−1 denote a process time period for the n-th stage and a process time period for the (n−1)th stage, respectively, and TPR(n−1), TTG(n−1), TAT(n−1), and RRM(n−1) denote a variation of the thickness the target, a target value of the thickness the target, an actual value of the thickness of the target, and a change rate of the actual value of the thickness, respectively, for the (n−1)th stage

13. The system of claim 12, wherein the control unit is configured to determine the first process time period according to the following sample control formula:
Sample control formula=ax+b
wherein a and b denote constants, and x denotes a removal rate.

14. The system of claim 13, wherein the control unit is configured to determine the sample control formula for the n-th stage according to the process control formula for the (n−1)th stage.

15. The system of claim 13, wherein the control unit is configured to determine the removal rate of the sample control formula based on a removal rate of an oxide wafer.

16. The system of claim 12, wherein the control unit is configured to determine second process time period according to the following reprocessing control formula:
Reprocessing control formula=[TTG(n)−TAT(n)]/RRR(n)
wherein TTG(n), TAT(n), and RRR(n) denote a target thickness of the material, an actual thickness of the material, and a reprocessing removal rate of the material for the n-th stage.

17. The system of claim 10, wherein the semiconductor manufacturing process is one selected from the group consisting of a rapid thermal treatment process, a chemical mechanical planarization (CMP) process, an overlay process, a physical deposition process, a chemical deposition process, and a spin coating process.

18. The system of claim 10, wherein a pattern density of a product applied to the (n−1)th stage in F(Z) is substantially equal to the pattern density of a product applied to the n-th stage in F(T).

19. A method of controlling a semiconductor device manufacturing process, the method comprising:
determining a first process time period according to the following sample control formula given by:
Sample control formula=ax+b,
wherein a and b denote constants, and x denotes a change rate;
performing a sample chemical mechanical planarization process during the first process time period;
measuring a variation of a target of a chemical mechanical planarization process after completion of the sample chemical mechanical planarization process; and
determining a third process time period for an n-th stage according to the following process control formula, if the variation of the target is within an allowable range:
Process control formula=F(T)×F(Z),
wherein F(T)=f(t)n/f(t)n−1, F(Z)=TPR(n−1)−[TTG(n−1)−TAT(n−1)]/RRM(n−1), f(t)n and f(t)n−1 denote a process time period for the n-th stage and a process time period for the (n−1)th stage, respectively, and TPR(n−1), TTG(n−1), TAT(n−1), and RRM(n−1) denote a variation of the target, a target value of the target, an actual value of the target, and a change rate of the actual value, respectively, for the (n−1)th stage.

20. The method of claim 19, wherein the predetermined value, the target value, the actual value, and the change rate are a predetermined thickness, a target thickness, an actual thickness, and a removal rate, respectively, of the target.

21. The method of claim 19, wherein the process is one selected from the group consisting of a rapid thermal treatment process, a chemical mechanical planarization (CMP) process, an overlay process, a physical deposition process, a chemical deposition process, and a spin coating process.

22. The method of claim 20, further comprising:
performing a main chemical mechanical planarization process for the n-th stage during the first process time period,
after the measuring of the thickness, if the thickness is out of the allowable range, determining a second process time period according to the following reprocessing control formula:
Reprocessing control formula=[TTG(n)−TAT(n)]/RRR(n)
wherein TTG(n), TAT(n), and RRR(n) denote a target thickness, an actual thickness, and a removal rate for the n-th stage; and
re-performing a CMP process on the CMP target during the second process time period.

23. The method of claim 19, wherein the sample control formula for the n-th stage is determined according to the process control formula for the (n−1)th stage.

24. The method of claim 19, wherein the sample control formula is determined based on an oxide wafer that is not patterned.

25. The method of claim 19, further comprising:
performing a main chemical mechanical planarization process for the n-th stage during the first process time period,
after the performing of the main chemical mechanical planarization process for the n-th stage, measuring a thickness of the target of the chemical mechanical planarization process;
determining a third process time period for an (n+1)th stage according to the process control formula, if the measured thickness is within the allowable range; and
performing a main chemical mechanical planarization process for the (n+1)th step during the third process time period.

26. The method of claim 25, after the performing of the main chemical mechanical planarization process for the (n+1)th stage, further comprising:
measuring a thickness of the target of the chemical mechanical planarization process;
determining a second process time period according to the reprocessing control formula, if the measured thickness is out of the allowable range; and
re-performing a chemical mechanical planarization process during the second process time period.
